(19) United States
(12) Patent Application Publication
(10) Pub. No.: US 2026/0247520 A1
(43) Pub. Date: Aug. 20, 2026

(54) CIRCUIT DEVICE AND ELECTROMECHANICAL UNIT

(71) Applicant: Panasonic Intellectual Property Management Co., Ltd., Osaka (JP)

(72) Inventors: Hideaki MIYAMOTO, Osaka (JP); Shingo ENOMOTO, Osaka (JP); Tsutomu SAKATA, Osaka (JP)

(21) Appl. No.: 19/159,536

(22) PCT Filed: Mar. 15, 2024
(86) PCT No.: PCT/JP2024/010290

§ 371 Date: Aug. 25, 2025

(30) Foreign Application Priority Data
Mar. 24, 2023 (JP) 2023-048885

(51) Int. Cl. H05K 1/02; H02K 11/33; H05K 1/14; H05K 5/02; H05K 7/20

(52) U.S. Cl. CPC H05K 1/0204; H02K 11/33; H05K 1/144; H05K 5/0209; H05K 7/20418; H05K 7/209

(57) ABSTRACT

A circuit device includes: a circuit board including a circuit component to drive a motor; a case that houses the circuit board; and a heat transfer member housed in the case and thermally connected to the circuit board. The case includes a peripheral wall portion and a heat sink joined to the peripheral wall portion. At least part of the circuit board is located between the heat sink and the heat transfer member. The heat transfer member is thermally connected to the heat sink and the at least part of the circuit board.

### TECHNICAL FIELD

The present disclosure relates to a circuit device and an electromechanical unit.

### BACKGROUND ART

Patent Literature 1 discloses a device including a circuit board for use to drive a motor. This device includes a supporting member for transferring, to a heat sink, heat generated by a heating element included in the circuit board. The supporting member is brought into contact with a surface, facing the heat sink, of the heating element.

### CITATION LIST

### Patent Literature

Patent Literature 1: JP 2017-123700 A

### SUMMARY OF INVENTION

According to the known technique described above, heat sometimes cannot be transferred sufficiently from the circuit board to the heat sink.

An object of the present disclosure is to provide a circuit device and an electromechanical unit which allow for effectively dissipating heat from a circuit board.

A circuit device according to an aspect of the present disclosure includes: a circuit board including a circuit component to drive a motor; a case that houses the circuit board; and a heat transfer member housed in the case and thermally connected to the circuit board. The case includes a peripheral wall portion and a heat sink joined to the peripheral wall portion. At least part of the circuit board is located between the heat sink and the heat transfer member. The heat transfer member is thermally connected to the heat sink and the at least part of the circuit board.

An electromechanical unit according to another aspect of the present disclosure includes the circuit device described above and a motor device coupled to the case of the circuit device.

### BRIEF DESCRIPTION OF DRAWINGS

FIG. 1 is a perspective view illustrating an electromechanical unit according to one embodiment;

FIG. 2 is an exploded perspective view illustrating a circuit device included in the electromechanical unit;

FIG. 3 is a bottom view illustrating a main part of the circuit device;

FIG. 4 is a cross-sectional view thereof taken along the plane A-A shown in FIG. 3;

FIG. 5 is an exploded perspective view also illustrating the main part of the circuit device;

FIG. 6 is an exploded perspective view illustrating a circuit device included in an electromechanical unit according to a first variation;

FIG. 7 is a bottom view illustrating a main part of the circuit device;

FIG. 8 is a cross-sectional view thereof taken along the plane B-B shown in FIG. 7;

FIG. 9 is a cross-sectional view thereof taken along the plane C-C shown in FIG. 7;

FIG. 10 is an exploded perspective view also illustrating the main part of the circuit device;

FIG. 11A is a perspective view illustrating a heat transfer member included in an electromechanical unit according to a second variation, and FIG. 11B is another perspective view illustrating the heat transfer member;

FIG. 12 is a perspective view illustrating an electromechanical unit according to a third variation;

FIG. 13 is a cross-sectional view illustrating a circuit device included in an electromechanical unit according to a fourth variation;

FIG. 14 is a cross-sectional view illustrating a circuit device included in an electromechanical unit according to a fifth variation;

FIG. 15 is a cross-sectional view illustrating a circuit device included in an electromechanical unit according to a sixth variation;

FIG. 16 is a cross-sectional view illustrating a circuit device included in an electromechanical unit according to a seventh variation; and

FIG. 17 is a cross-sectional view illustrating a circuit device included in an electromechanical unit according to an eighth variation.

### DESCRIPTION OF EMBODIMENTS

A circuit device and electromechanical unit according to the present disclosure will now be described with reference to the accompanying drawings. Note that the drawings to be referred to in the following description of embodiments are all schematic representations. Thus, the ratio of the dimensions (including thicknesses) of respective constituent elements illustrated on the drawings does not always reflect their actual dimensional ratio.

### 1. Embodiment

### (1) Overall Structure of Electromechanical Unit

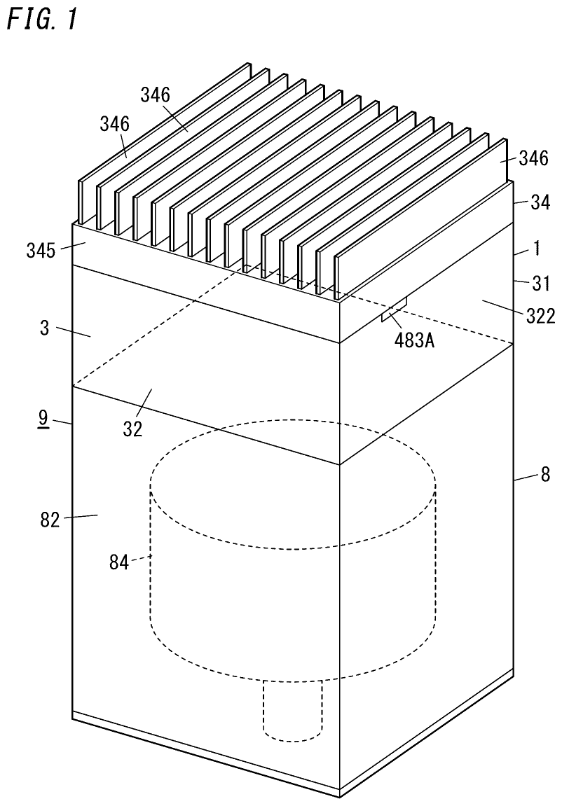

FIG. 1 shows an overall appearance of an electromechanical unit 9 according to one embodiment. The electromechanical unit 9 according to the one embodiment includes, as an integrated structure, a circuit device 1 and a motor device 8 to be driven by the circuit device 1. The circuit device 1 and the motor device 8 are mechanically and electrically connected to each other. The circuit device 1 supplies electric power to the motor device 8 to drive the motor device 8 with the electric power thus supplied. The circuit device 1 controls the operation of the motor device 8 by controlling the electric power to be supplied to the motor device 8.

### (2) Circuit Device

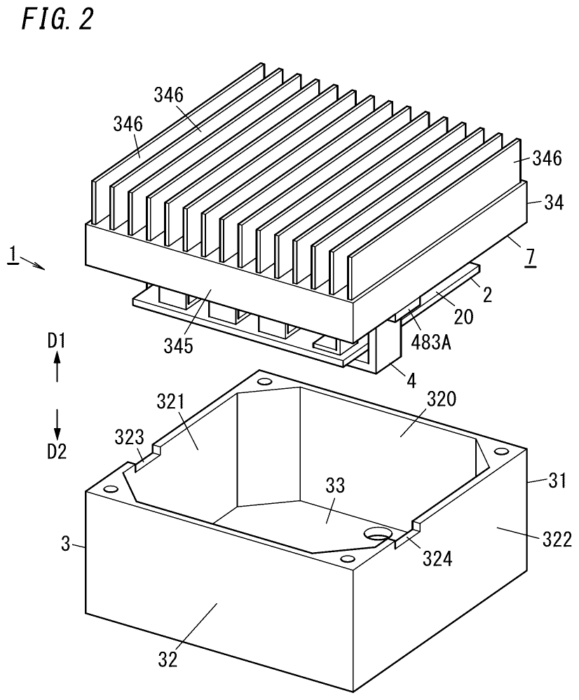

FIG. 2 shows the circuit device 1 according to the one embodiment. The circuit device 1 includes a circuit board 2, a case 3 housing the circuit board 2, and a heat transfer member 4. The heat transfer member 4 is housed in the case 3 so as to be thermally connected to the circuit board 2.

### (2-1) Circuit Board

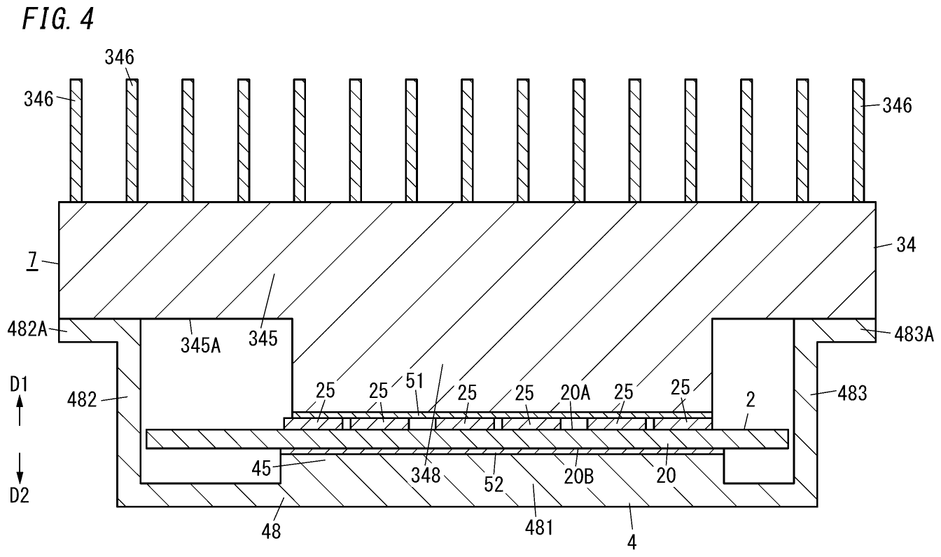

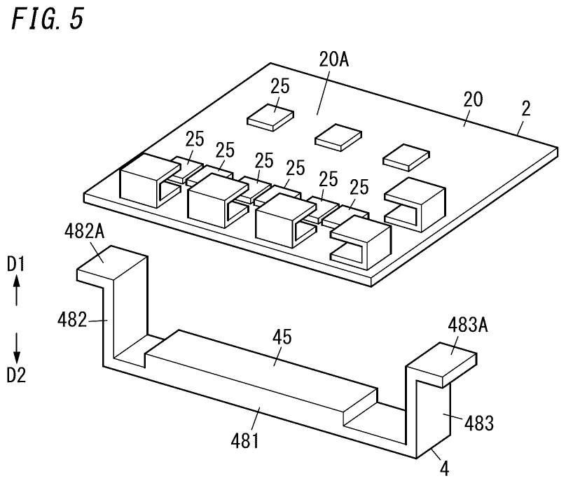

The circuit board 2 includes a board 20 and a plurality of circuit components 25 mounted on the board 20 (refer to FIGS. 4 and 5). The board 20 has the shape of a flat plate with thickness and has a first surface 20A and a second surface 20B facing away from each other in a thickness direction.

The first surface 20A and the second surface 20B are both flat. However, this should not be construed as limiting. Alternatively, both or either of the first surface 20A and the second surface 20B may be unflat.

The first surface 20A of the board 20 is a surface facing a heat sink 34 (to be described later) included in the case 3. The second surface 20B of the board 20 is a surface facing a bottom wall portion 33 (to be described later) included in the case 3.

The plurality of circuit components 25 includes an element of a driver circuit and an element of a control circuit. Examples of the elements of the driver circuit include a field effect transistor (hereinafter abbreviated as “FET”) and an insulated gate bipolar transistor (hereinafter abbreviated as “IGBT”). Examples of the elements of the control circuit include a microcontroller unit (hereinafter abbreviated as “MCU”). The plurality of circuit components 25 are mounted on the first surface 20A of the board 20.

In one embodiment, the plurality of circuit components 25 are mounted only on the first surface 20A of the board 20. However, this should not be construed as limiting. Alternatively, the plurality of circuit components 25 may be mounted on both the first surface 20A and second surface 20B of the board 20.

### (2-2) Case

As shown in FIG. 2, the case 3 includes a peripheral wall portion 32, the bottom wall portion 33, and the heat sink 34. The peripheral wall portion 32 and the bottom wall portion 33 are formed integrally out of a thermal conductive material. The thermal conductive material for the peripheral wall portion 32 and the bottom wall portion 33 is, for example, aluminum. However, this should not be construed as limiting. The heat sink 34 is formed out of the thermal conductive material separately from the peripheral wall portion 32 and bottom wall portion 33. The thermal conductive material for use to form the heat sink 34 is, for example, aluminum. However, this should not be construed as limiting.

The peripheral wall portion 32 has the profile of a rectangular frame. The peripheral wall portion 32 includes a pair of sidewalls 321, 322 facing each other. A cutout 323 is provided at an end edge of the sidewall 321 in a direction in which the heat sink 34 is located with respect to the peripheral wall portion 32 (hereinafter referred to as a “first direction D1”). In the same way, a cutout 324 is provided at an end edge of the sidewall 322 in the first direction D1. Each of the cutouts 323, 324 is depressed in a direction in which the peripheral wall portion 32 is located with respect to the heat sink 34 (hereinafter referred to as a “second direction D2”).

The first direction D1 and the second direction D2 are opposite from each other. In other words, the first direction D1 is a direction in which an opening 320 is located with respect to the bottom wall portion 33 of the case 3 and a direction in which the heat sink 34 is located with respect to the bottom wall portion 33 of the case 3. The second direction D2 is, in other words, a direction in which the bottom wall portion 33 is located with respect to the opening 320 of the case 3 and a direction in which the bottom wall portion 33 is located with respect to the heat sink 34 of the case 3.

The bottom wall portion 33 is formed integrally with the peripheral wall portion 32 to close an opening on a first side of the peripheral wall portion 32 having a rectangular frame shape. Note that the peripheral wall portion 32 and the bottom wall portion 33 may be formed separately. A case body 31 having the shape of a bottomed cylinder is formed by the peripheral wall portion 32 and the bottom wall portion 33.

The heat sink 34 includes a lid portion 345, having a flat plate shape, to be joined to the peripheral wall portion 32 and a plurality of fins 346 protruding from the lid portion 345 in the first direction D1. The plurality of fins 346 protrudes from the lid portion 345 in the first direction D1 to be arranged parallel to each other.

The lid portion 345 of the heat sink 34 is joined to the peripheral wall portion 32 to close the opening 320 on a second side of the peripheral wall portion 32. In other words, the heat sink 34 is joined to the case body 31 to close the opening 320 of the case body 31 having the bottomed cylinder shape.

As shown in FIG. 4, the lid portion 345 is provided with a connection portion 348. The connection portion 348 is a portion to be connected thermally to the circuit board 2. The connection portion 348 is configured as a protruding portion protruding from the lid portion 345 in the second direction D2.

The connection portion 348 of the heat sink 34 is thermally connected to at least one circuit component 25 mounted on the circuit board 2. In one embodiment, the connection portion 348 is thermally connected to the plurality of circuit components 25 mounted on the circuit board 2.

A thermal conductive member 51 is interposed between the connection portion 348 of the heat sink 34 and the at least one circuit component 25 on the circuit board 2. The thermal conductive member 51 is in contact with the connection portion 348 of the heat sink 34 and also in contact with the plurality of circuit components 25 (e.g., a plurality of circuit components 25 implemented as FETs or IGBTs). The connection portion 348 is thermally connected, via the thermal conductive member 51, to the plurality of circuit components 25.

The thermal conductive member 51 has, for example, a sheet shape. Optionally, no thermal conductive member 51 may be interposed between the connection portion 348 of the heat sink 34 and at least one circuit component 25 on the circuit board 2.

### (2-3) Heat Transfer Member

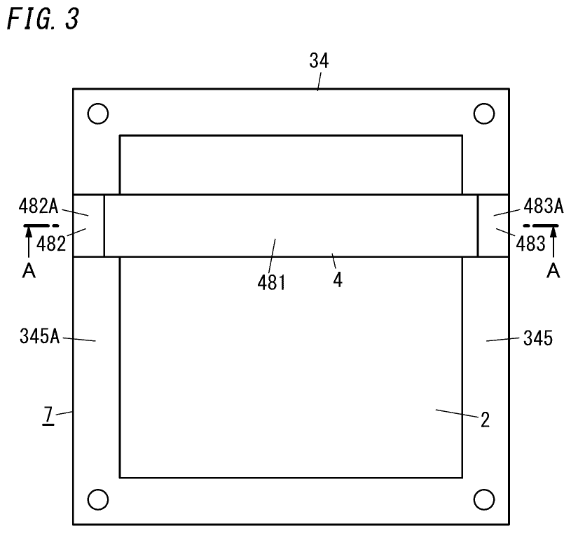

As shown in FIGS. 2-5 and other drawings, the heat transfer member 4 is formed out of a thermal conductive material separately from the case body 31 and the heat sink 34. The thermal conductive material for the heat transfer member 4 is, for example, aluminum. However, the thermal conductive material is not limited to aluminum.

The heat transfer member 4 includes a member body 48 and a connection portion 45 provided for the member body 48. The member body 48 is a portion to be thermally connected to the heat sink 34. The connection portion 45 is a portion to be thermally connected to the circuit board 2.

The member body 48 includes: a first portion 481 having the shape of an elongate plate; a second portion 482 protruding, in the first direction D1, from a first end portion along a longitudinal axis of the first proportion 481; and a third portion 483 protruding, in the first direction D1, from a second end portion along the longitudinal axis of the first proportion.

In one embodiment, the first portion 481, the second portion 482, and the third portion 483 are formed integrally. However, this should not be construed as limiting. Alternatively, the second portion 482 may also be formed separately from the first portion 481, and the third portion 482 may also be formed separately from the first portion 481.

For example, if the first portion 481, the second portion 482, and the third portion 483 are formed separately from each other, a second member 482 and a third member 483, each formed out of a thermal conductive material in the shape of a cylinder or a polygonal prism spacer, may be mechanically and thermally connected to a first member 481 formed out of the thermal conductive material. The second member 482 and the third member 483 may be thermally and mechanically connected, by an appropriate connecting means, to the first portion 481. The connecting means is, for example, fastening a screw.

A protruding portion 482A of the second portion 482 is bent perpendicularly to form an L-member. In the same way, a protruding portion 483A of the third portion 483 is also bent perpendicularly to form an L-member. As used herein, the term “perpendicularly” may refer to not only a right angle in a strict sense of the word but also an angle which may be regarded as a substantially right angle. A direction in which the protruding portion 482A of the second portion 482 is bent to extend and a direction in which the protruding portion 483A of the third portion 483 is bent to extend are opposite from each other.

In one embodiment, the connection portion 45 of the heat transfer member 4 forms part of the first portion 481. The connection portion 45 has a shape protruding in the first direction D1 with respect to the other parts of the first portion 481. The other parts of the first portion 481 are, in other words, the entire first portion 481 but the connection portion 45.

The connection portion 45 is thermally connected to the board 20 of the circuit board 2. The connection portion 45 is thermally connected, on the second surface 20B of the board 20, to the reverse side of at least one circuit component 25. In one embodiment, the connection portion 45 is thermally connected, on the second surface 20B of the board 20, to the reverse side of each of the plurality of circuit components 25 (e.g., a plurality of circuit components 25 implemented as FETs or IGBTs).

A thermal conductive member 52 is interposed between the connection portion 45 of the heat transfer member 4 and the board 20. The thermal conductive member 52 is in contact with not only the connection portion 45 of the heat transfer member 4 but also the board 20. The connection portion 45 is thermally connected, via the thermal conductive member 52 and the board 20, to the plurality of circuit components 25 (e.g., a plurality of circuit components 25 implemented as FETs or IGBTs).

The thermal conductive member 52 has, for example, a sheet shape. Optionally, no thermal conductive member 52 may be interposed between the connection portion 45 of the heat transfer member 4 and the board 20.

The second portion 482 and third portion 483 of the heat transfer member 4 are mechanically and thermally connected to the heat sink 34. More particularly, the protruding portion 482A of the second portion 482 is in contact with a surface 345A which is a surface, facing the second direction D2, of the lid portion 345 of the heat sink 34 and mechanically and thermally connected to a surface 345A of the lid portion 345. It is preferable that the protruding portion 482A of the second portion 482 be directly in contact with the lid portion 345. Alternatively, a thermal conductive member may also be interposed between the protruding portion 482A of the second portion 482 and the lid portion 345.

In the same way, the protruding portion 483A of the third portion 483 is in contact with a surface 345A which is a surface, facing the second direction D2, of the lid portion 345 of the heat sink 34 and mechanically and thermally connected to the surface 345A of the lid portion 345. It is preferable that the protruding portion 483A of the third portion 483 be directly in contact with the lid portion 345. Alternatively, a thermal conductive member may also be interposed between the protruding portion 483A of the third portion 483 and the lid portion 345.

### (2-4) Integrated Structure

An integrated structure 7 shown in FIGS. 2-4 is formed by joining the circuit board 2 and the heat transfer member 4 to the heat sink 34. In the integrated structure 7, the circuit board 2 including the board 20 and the plurality of circuit components 25 is sandwiched between the heat sink 34 and the heat transfer member 4. The circuit board 2 is located between the heat sink 34 and the heat transfer member 4 mechanically and thermally connected to the heat sink 34.

A circuit device 1 according to one embodiment is formed by joining the case 3 to this integrated structure 7 (refer to FIG. 2). With the case 3 joined to the integrated structure 7, the protruding portion 482A of the second portion 482 included in the heat transfer member 4 is inserted into the cutout 323 of the sidewall 321 of the case 3 and the protruding portion 483A of the third portion 483 included in the heat transfer member 4 is inserted into the cutout 324 of the sidewall 322 of the case 3. It is preferable that the protruding portion 482A of the second portion 482 be fitted into the cutout 323 of the case 3 and the protruding portion 483A of the third portion 483 be fitted into the cutout 324 of the case 3.

### (3) Motor Device

As shown in FIG. 1, the motor device 8 includes a motor case 82 serving as an outer shell of the motor device 8 and a motor 84 housed in the motor case 82. The motor case 82 is formed out of a thermal conductive material. The thermal conductive material for the motor case 82 is, for example, aluminum. However, this should not be construed as limiting.

The motor case 82 is mechanically connected to the case 3 serving as an outer shell of the circuit device 1. In one embodiment, the motor case 82 is thermally connected to the case 3 of the circuit device 1. The motor case 82 is preferably directly in contact with the case 3 of the circuit device 1, but a thermal conductive material may also be interposed between the motor case 82 and the case 3 of the circuit device 1.

The motor 84 is electrically connected to the circuit board 2 housed in the circuit device 1. The motor 84 is driven in rotation with electric power supplied from the circuit device 1.

### (4) Advantages

In the electromechanical unit 9 according to the one embodiment described above, the heat sink 34 separately includes the connection portion 348 thermally connected to the circuit board 2 and a portion thermally connected to the heat transfer member 4. Therefore, the path that thermally connects the circuit board 2 and the heat sink 34 to each other includes a first path directly leading from the circuit board 2 to the heat sink 34, not via the heat transfer member 4 and a second path leading from the circuit board 2 to the heat sink 34 via the heat transfer member 4. The first path is a path for transferring heat to the heat sink 34 from the surface side of the circuit board 2 and the second path is a path for transferring heat to the heat sink 34 from the reverse side of the circuit board 2. The first path and the second path are independent of each other. The electromechanical unit 9 according to the one embodiment allows for effectively transferring heat from the circuit board 2 to the heat sink 34 via these two paths on the surface and reverse sides, respectively.

Therefore, the electromechanical unit 9 according to the one embodiment allows for effectively dissipating heat from the circuit board 2 to the external environment via the heat sink 34.

### 2. Variations

The one embodiment described above is only an exemplary one of various embodiments of the present disclosure and should not be construed as limiting. Rather, the one embodiment may be readily modified in various manners, as will be described in the variations to be enumerated below, depending on a design choice or any other factor without departing from the scope of the present disclosure. Note that any constituent element of the variations to be described below, having the same configuration as a counterpart of the above-described embodiment, will be designated by the same reference numeral as that counterpart's, and a detailed description thereof will be omitted as appropriate herein.

### (1) First Variation

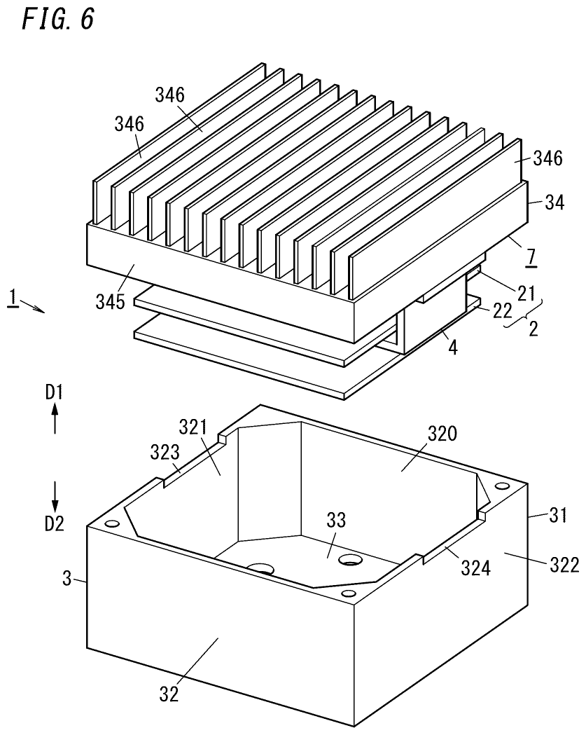

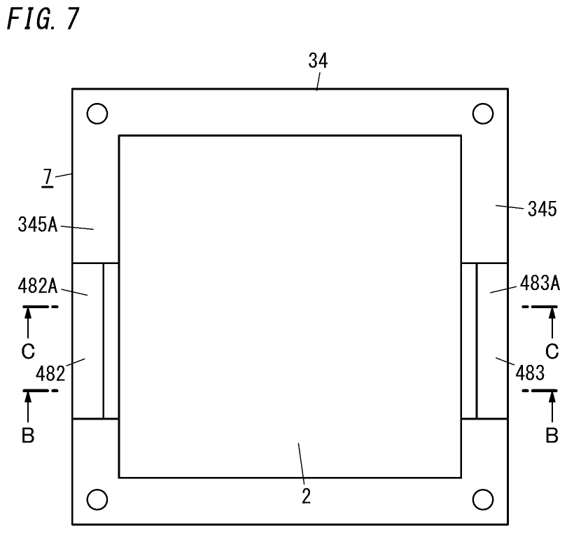

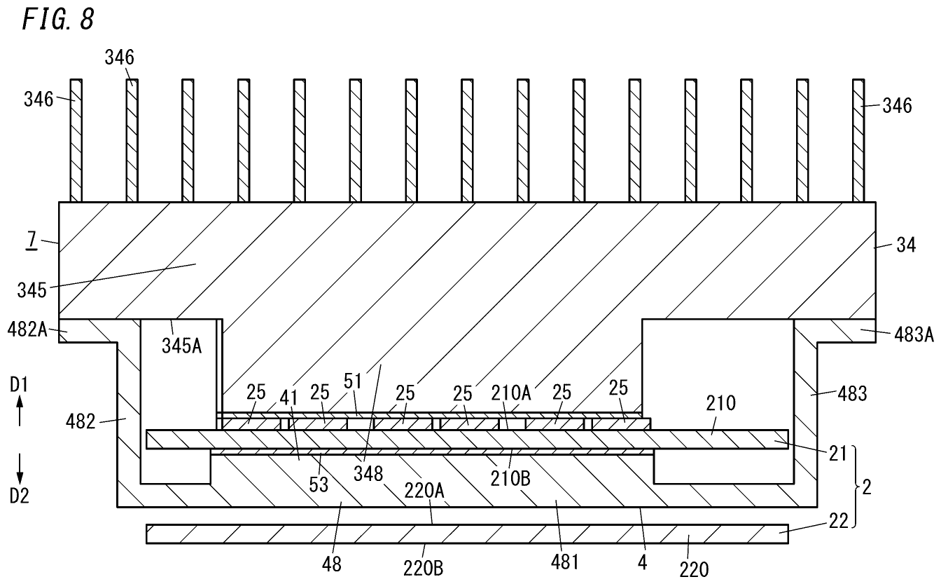

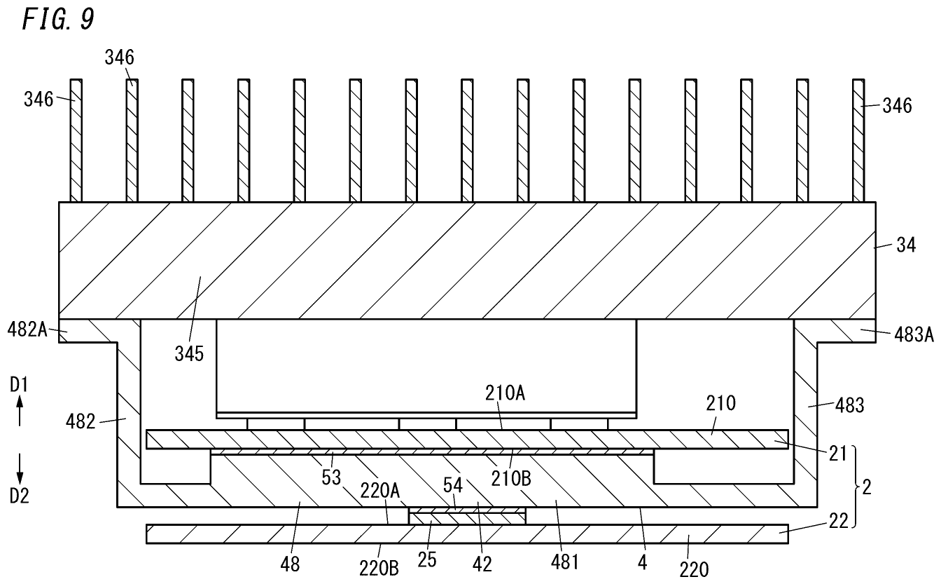

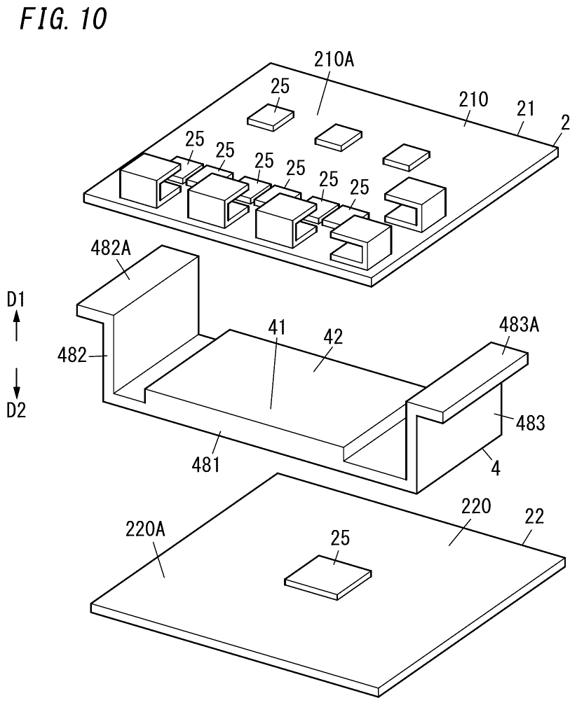

FIGS. 6-10 show an integrated structure 7 included in an electromechanical unit 9 according to a first variation. In the first variation, circuit boards 2 included in a circuit device 1 include a first circuit board 21 and a second circuit board 22. The first circuit board 21 and the second circuit board 22 are formed separately from each other and electrically connected to each other.

The first circuit board 21 and the second circuit board 22 are arranged to be parallel to each other. As used herein, the term “parallel” may refer to not only a situation where two members are arranged exactly parallel to each other in a strict sense of the word but also a situation where the two members arranged may be regarded as substantially parallel to each other. The first circuit board 21 is located in the first direction D1 with respect to the second circuit board 22. The distance between the first circuit board 21 and the heat sink 34 is shorter than the distance between the second circuit board 22 and the heat sink 34.

The first circuit board 21 is a circuit board serving as a power circuit for supplying electric power to drive a motor. The first circuit board 21 includes a board 210 and at least one circuit component 25 mounted on the board 210. The board 210 has the shape of a flat plate with thickness and has a first surface 210A and a second surface 210B facing away from each other in the thickness direction.

The first surface 210A and the second surface 210B are both flat. However, this should not be construed as limiting. Alternatively, both or either of the first surface 210A and the second surface 210B may be unflat.

The first surface 210A of the board 210 is a surface facing the first direction D1 and is, in other words, a surface facing a heat sink 34. The second surface 210B of the board 210 is a surface facing the second direction D2 and is, in other words, a surface facing the second circuit board 22.

The at least one circuit component 25 mounted on the first circuit board 21 is implemented as, for example, an FET. In the first variation, a plurality of circuit components 25 are mounted on the first surface 210A of the board 210.

The second circuit board 22 is a circuit board serving as a control circuit to activate the power circuit. The second circuit board 22 includes a board 220 and at least one circuit component 25 mounted on the board 220. The board 220 has the shape of a flat plate with thickness and has a first surface 220A and a second surface 220B facing away from each other in the thickness direction. The first surface 220A and the second surface 220B are both flat. However, this should not be construed as limiting. Alternatively, both or either of the first surface 220A and the second surface 220B may possibly be unflat.

The first surface 220A of the board 220 is a surface facing the first direction D1. The first surface 220A is a surface facing the first circuit board 21 and is, in other words, a surface facing the heat sink 34. The second surface 210B of the board 210 is a surface facing the second direction D2 and is, in other words, a surface facing the bottom wall portion 33 of the case 3.

The at least one circuit component 25 mounted on the second circuit board 22 is implemented as, for example, an MCU. In the first variation, the circuit component 25 implemented as an MCU is mounted in a central area of the first surface 220A of the board 220.

The heat transfer member 4 is not only thermally connected to the first circuit board 21, but also thermally connected to the second circuit board 22. That is to say, the heat transfer member 4 is thermally connected to both the first circuit board 21 and the second circuit board 22.

The heat transfer member 4 includes a member body 48 and a first connection portion 41 and a second connection portion 42 provided for the member body 48. The first connection portion 41 is a portion to be thermally connected to the first circuit board 21 and the second connection portion 42 is a portion to be thermally connected to the second circuit board 22.

In the first variation, each of the first connection portion 41 and second connection portion 42 of the heat transfer member 4 forms part of the first portion 481. The first connection portion 41 and the second connection portion 42 are located side by side in a direction intersecting at right angles with a longitudinal axis of the first portion 481 and are continuous with each other.

The first connection portion 41 is thermally connected to the board 210 of the first circuit board 21. The first connection portion 41 is thermally connected, on the second surface 210B of the board 210, to the reverse side of at least one circuit component 25. In the first variation, the first connection portion 41 is thermally connected, on the second surface 210B of the board 210, to the reverse side of each of the plurality of circuit components 25 (e.g., a plurality of circuit components 25 implemented as FETs or IGBTs).

A thermal conductive member 53 is interposed between the first connection portion 41 of the heat transfer member 4 and the board 210 of the first circuit board 21. The thermal conductive member 53 is in contact with not only the first connection portion 41 of the heat transfer member but also the board 210 of the first circuit board 21. The first connection portion 41 is thermally connected, via the thermal conductive member 53 and the board 210, to the plurality of circuit components 25 (e.g., a plurality of circuit components 25 implemented as FETs or IGBTs).

The thermal conductive member 53 has, for example, a sheet shape. Optionally, no thermal conductive member 53 may be interposed between the first connection portion 41 of the heat transfer member 4 and the board 210 of the first circuit board 21.

The second connection portion 42 is thermally connected to the circuit component 25 mounted on the second circuit board 22. A thermal conductive member 54 is interposed between the second connection portion 42 of the heat transfer member 4 and the circuit component 25 on the second circuit board 22. The thermal conductive member 54 is in contact with not only the second connection portion 42 of the heat transfer member 4 but also the circuit component 25 on the second circuit board 22. The second connection portion 42 is thermally connected, via the thermal conductive member 54, to the circuit component 25 (e.g., a circuit component 25 implemented as MCU).

The thermal conductive member 54 has, for example, a sheet shape. Optionally, no thermal conductive member 54 may be interposed between the second connection portion 42 of the heat transfer member 4 and the circuit component 25 on the second circuit board 22.

In the first variation, an integrated structure 7 is formed by joining the first circuit board 21, the second circuit board 22, and the heat transfer member 4 to the heat sink 34. In the integrated structure 7, the first circuit board 21 is sandwiched between the heat sink 34 and the heat transfer member 4 and the heat transfer member 4 is sandwiched between the first circuit board 21 and the second circuit board 22. The first circuit board 21 is located in the first direction D1 with respect to the heat transfer member 4, and the second circuit board 22 is located in the second direction D2 with respect to the heat transfer member 4.

In the electromechanical unit 9 according to the first variation which includes this integrated structure 7, heat is transferred from the first circuit board 21 to the heat sink 34 via two paths. These two paths are independent of each other.

One of the two paths is a path along which heat is directly transferred from the at least one circuit component 25 on the first circuit board 21 to the heat sink 34 not via the heat transfer member 4. The other path is a path along which heat is transferred from the board 20 of the first circuit board 21 to the heat sink 34 via the heat transfer member 4. A path along which heat is transferred from the second circuit board 22 to the heat sink 34 is the path along which heat is transferred to the heat sink 34 via the heat transfer member 4.

Therefore, the electromechanical unit 9 according to the one embodiment allows for effectively dissipating heat from the first circuit board 21 and the second circuit board 22 to the external environment via the heat sink 34.

### (2) Second Variation

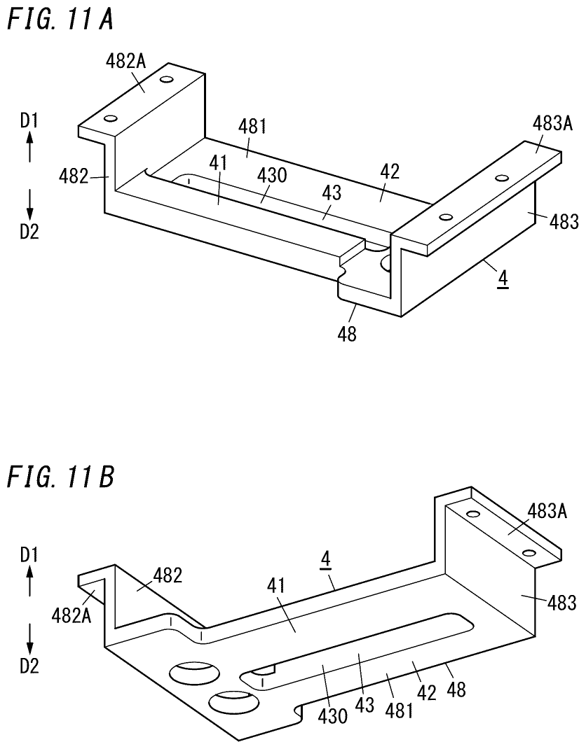

FIGS. 11A and 11B show a heat transfer member 4 included in an electromechanical unit 9 according to a second variation. The fundamental configuration of the electromechanical unit 9 according to the second variation is the same as that of the first variation. Note that any constituent element of the second variation to be described below, having the same configuration as a counterpart of the first variation, will be designated by the same reference numeral as that counterpart's, and a detailed description thereof will be omitted as appropriate herein.

The heat transfer member 4 is, as in the first variation, thermally connected to the first circuit board 21 and the second circuit board 22.

The heat transfer member 4 includes a member body 48, and a first connection portion 41, a second connection portion 42, and a thermal insulator 43, which are provided for the member body 48.

The first connection portion 41 and second connection portion 42 of the heat transfer member 4 are arranged side by side in a direction intersecting at right angle with the longitudinal axis of the member body 48. The thermal insulator 43 is provided between the first connection portion 41 and the second connection portion 42. The direction in which the first connection portion 41 and the second connection portion 42 are arranged is a direction perpendicular to not only the first direction D1 but also the second direction D2.

The thermal insulator 43 is a portion that interrupts the transfer of heat between the first connection portion 41 and the second connection portion 42. In the second variation, the thermal insulator 43 is an air gap 430 provided for the member body 48. The air gap 430 is provided as a slit extending linearly along the longitudinal axis of the member body 81.

The air gap 430 is provided for the first portion 481. The air gap 430 penetrates through the first portion 481. A direction in which the air gap 430 penetrates through the first portion 481 and a direction in which the first connection portion 41 and the second connection portion 42 are arranged are perpendicular to each other. The air gap 430 does not have to penetrate through the first portion 418 but may also be a non-penetrating air gap. Alternatively, the thermal insulator 43 does not have to be the air gap 430. For example, the thermal insulator 43 may also include a porous portion in which multiple pores are formed. The thermal insulator 43 may also include a thermal insulation member interposed between the first connection portion 41 and the second connection portion 42.

In the electromechanical unit 9 according to the second variation which includes this heat transfer member 4, heat is transferred, via the heat transfer member 4 including the first connection portion 41 and the second connection portion 42, not only from the first circuit board 21 to the heat sink 34 but also from the second circuit board 22 to the heat sink 34. In addition, in the electromechanical unit 9 according to the second variation, the thermal insulator 43 is provided for the heat transfer member 4, thereby reducing the transfer of the heat generated in the first circuit board 21 to the second circuit board 22 and the transfer of the heat generated in the second circuit board 22 to the first circuit board 21.

Therefore, the electromechanical unit 9 according to the second variation allows for effectively dissipating heat from the first circuit board 21 to the external environment via the heat sink 34 and also effectively dissipating heat from the second circuit board 22 to the external environment via the heat sink 34.

### (3) Third Variation

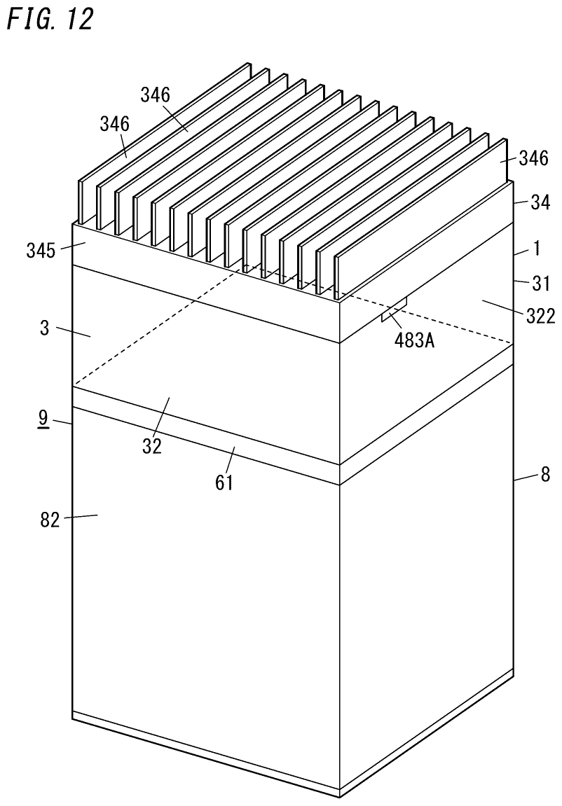

FIG. 12 shows an electromechanical unit 9 according to a third variation. The electromechanical unit 9 according to the third variation further includes a thermal insulator member 61.

The thermal insulator member 61 is interposed between the motor case 82 serving as an outer shell of the motor device 8 and the case 3 serving as an outer shell of the circuit device 1. The thermal insulator member 61 is formed out of a thermal insulation material in a rectangular flat plate shape. The thermal insulation material for the thermal insulator member 61 is, for example, a fluororesin. However, this should not be construed as limiting. Examples of the fluororesin for use as the thermal insulation material include polytetrafluoroethylene (hereinafter abbreviated as “PTFE”). Examples of the thermal insulation material also include polyetheretherketone (hereinafter abbreviated as “PEEK”) and polyimide (hereinafter abbreviated as “PI”). The thermal insulator member 61 is provided to interrupt the transfer of heat between the motor device 8 and the circuit device 1.

The thermal insulator member 61 may be directly in contact with the motor case 82, or another member may also be interposed between the thermal insulator member 61 and the motor case 82. In the same way, the thermal insulator member 61 may be directly in contact with the case 3 of the circuit device 1, or another member may also be interposed between the thermal insulator member 61 and the case 3 of the circuit device 1.

The electromechanical unit 9 according to the third variation which includes the thermal insulator member 61 described above allows for reducing the transfer of the heat generated in the motor device 8 to the heat sink 34 through the peripheral wall portion 32 of the circuit device 1. This allows for reducing the transfer of the heat generated in the motor device 8 to the circuit board 2 through the peripheral wall portion 32 and heat sink 34 of the circuit device 1. Note that the heat generated in the motor device 8 may be dissipated via an appropriate structure to fix the motor device 8 inside the mechanism.

### (4) Fourth Variation

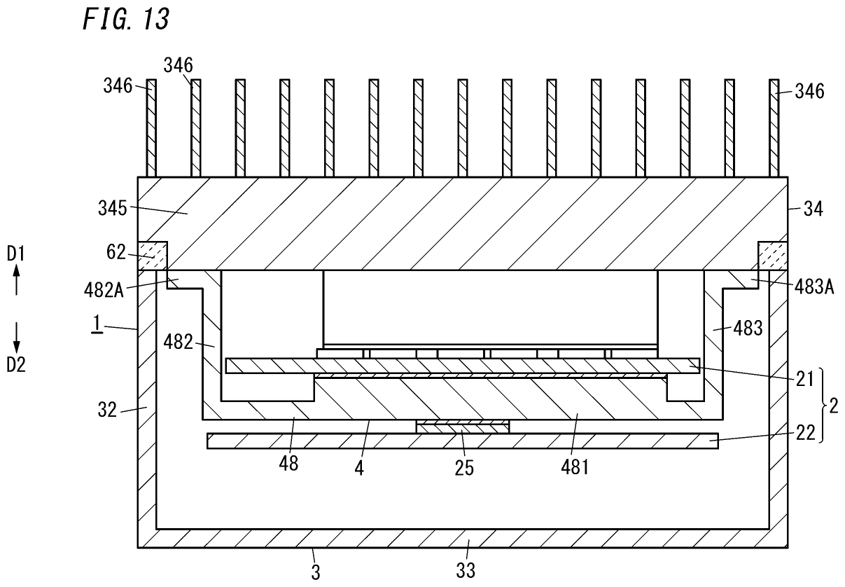

FIG. 13 is a sectional view of a circuit device 1 included in an electromechanical unit 9 according to a fourth variation. The fundamental configuration of the electromechanical unit 9 according to the fourth variation is the same as that of the first variation. Note that any constituent element of the fourth variation to be described below, having the same configuration as a counterpart of the first variation, will be designated by the same reference numeral as that counterpart's, and a detailed description thereof will be omitted as appropriate herein.

The electromechanical unit 9 according to the fourth variation further includes a thermal insulator member 62 included in the circuit device 1. The thermal insulator member 62 is interposed between the peripheral wall portion 32 forming one part of the case 3 of the circuit device 1 and the heat sink 34 forming another part of the case 3. The thermal insulator member 62 is formed out of a thermal insulation material. The thermal insulation material for the thermal insulator member 62 is, for example, a fluororesin. However, this should not be construed as limiting. Examples of the fluororesin for use as the thermal insulation material include PTFE, PEEK, and PI. The thermal insulator member 62 is interposed to interrupt the transfer of heat between the peripheral wall portion 32 and the heat sink 34. The thermal insulator member 62 is formed, for example, in a rectangular ring shape, but may also have another shape. For example, instead of having the shape of a ring connected along the entire circumference, the thermal insulator member 62 may also have the shape of an imperfect ring disconnected at least at one point along the entire circumference.

In the electromechanical unit 9 according to the fourth variation, the second portion 482 and the third portion 483 included in the heat transfer member 4 are mechanically and thermally connected to the heat sink 34, but are preferably neither mechanically nor thermally connected to the peripheral wall portion 32.

The thermal insulator member 62 may be directly in contact with the peripheral wall portion 32, or another member may also be interposed between the thermal insulator member 62 and the peripheral wall portion 32. In the same way, the thermal insulator member 62 may be directly in contact with the heat sink 34, or another member may also be interposed between the thermal insulator member 62 and the heat sink 34.

The electromechanical unit 9 according to the fourth variation which includes the thermal insulator member 62 described above allows for reducing the transfer of the heat generated in the motor device 8 to the heat sink 34 through the peripheral wall portion 32 of the circuit device 1. This allows for reducing the transfer of the heat generated in the motor device 8 to the circuit board 2 through the peripheral wall portion 32 and heat sink 34 of the circuit device 1.

### (5) Fifth Variation

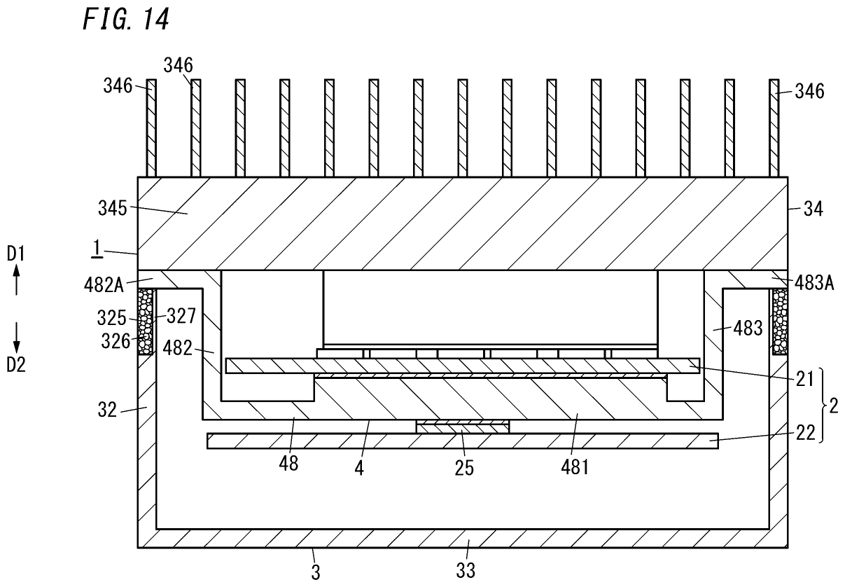

FIG. 14 is a sectional view of a circuit device 1 included in an electromechanical unit 9 according to a fifth variation. The fundamental configuration of the electromechanical unit 9 according to the fifth variation is the same as that of the first variation. Note that any constituent element of the fifth variation to be described below, having the same configuration as a counterpart of the first variation, will be designated by the same reference numeral as that counterpart's, and a detailed description thereof will be omitted as appropriate herein.

Part of the peripheral wall portion 32 included in the circuit device 1 according to the fifth variation is configured as a thermal insulation structure 325 having a lower thermal conductivity than the rest of the peripheral wall portion 32. The thermal insulation structure 325 is a porous structure 326 having a large number of pores. The peripheral wall portion 32 according to the fifth variation may be manufactured by forming only a part of the peripheral wall portion 32 as the porous structure 326 when a peripheral wall portion 32 of aluminum is formed by using a 3D printer, for example.

The thermal insulation structure 325 is formed at an end portion of the peripheral wall portion 32 in the first direction D1, but may also be formed elsewhere on the peripheral wall portion 32. It is preferable that the thermal insulation structure 325 have the shape of a ring connected along the entire circumference of the peripheral wall portion 32. Alternatively, the thermal insulation structure 325 may also have the shape of an imperfect ring disconnected at least at one point along the entire circumference of the peripheral wall portion 32.

In the fifth variation, part of the peripheral wall portion 32 located inside the porous structure 326 is configured as a non-porous solid structure 327. It is preferable that the solid structure 327 have the shape of a ring connected along the entire circumference of the peripheral wall portion 32. Alternatively, the solid structure 327 may also have the shape of an imperfect ring disconnected at least at one point along the entire circumference of the peripheral wall portion 32.

The electromechanical unit 9 according to the fifth variation having the porous structure 326 described above allows for reducing the transfer of the heat generated in the motor device 8 to the heat sink 34 through the peripheral wall portion 32 of the circuit device 1. This allows for reducing the transfer of the heat generated in the motor device 8 to the circuit board 2 through the peripheral wall portion 32 and heat sink 34 of the circuit device 1. Also, the porous structure 326 forms part of the peripheral wall portion 32, which contributes to reducing the weight of the peripheral wall portion 32. In addition, the electromechanical unit 9 according to the fifth variation having the solid structure 327 described above provides the solid structure 327 inside the porous structure 326, thus preventing, with more reliability, foreign substances from entering the case 3.

### (6) Sixth Variation

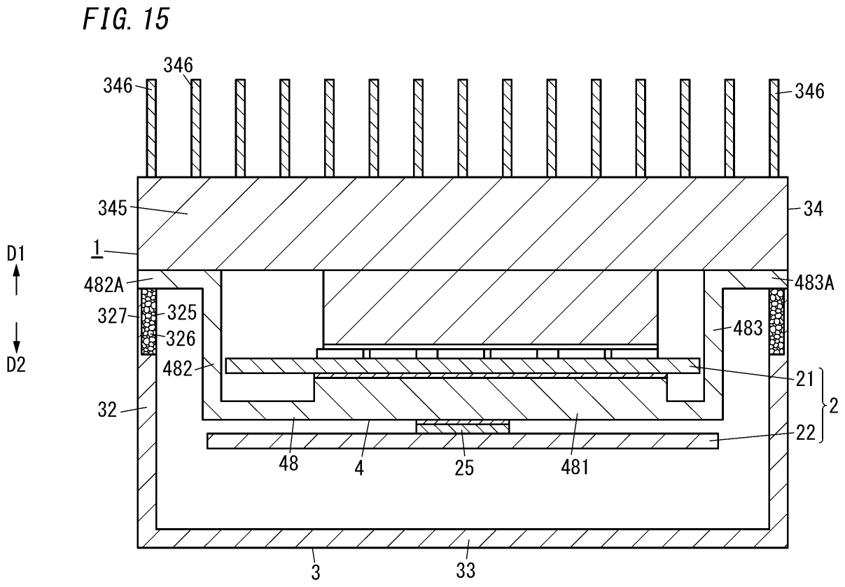

FIG. 15 is a sectional view of a circuit device 1 included in an electromechanical unit 9 according to a sixth variation. The fundamental configuration of the electromechanical unit 9 according to the sixth variation is the same as that of the fifth variation. Note that any constituent element of the sixth variation to be described below, having the same configuration as a counterpart of the fifth variation, will be designated by the same reference numeral as that counterpart's, and a detailed description thereof will be omitted as appropriate herein.

In the circuit device 1 according to the sixth variation, the positional relationship between the porous structure 326 forming part of the peripheral wall portion 32 and the solid structure 327 adjacent to the porous structure 326 is different from that of the fifth variation.

In the sixth variation, part of the peripheral wall portion 32 located outside the porous structure 326 is configured as the solid structure 327. It is preferable that the solid structure 327 have the shape of a ring connected along the entire circumference of the peripheral wall portion 32. Alternatively, the solid structure 327 may also have the shape of an imperfect ring disconnected at least at one point along the entire circumference of the peripheral wall portion 32. The peripheral wall portion 32 according to the sixth variation may also be manufactured by forming only a part of the peripheral wall portion 32 as the porous structure 326 when a peripheral wall portion 32 of aluminum is formed by using a 3D printer, for example.

The electromechanical unit 9 according to the sixth variation provides the solid structure 327 outside the porous structure 326 to serve as a protective cover for the porous structure 326, thus preventing, with more reliability, foreign substances from entering the case 3.

### (7) Seventh Variation

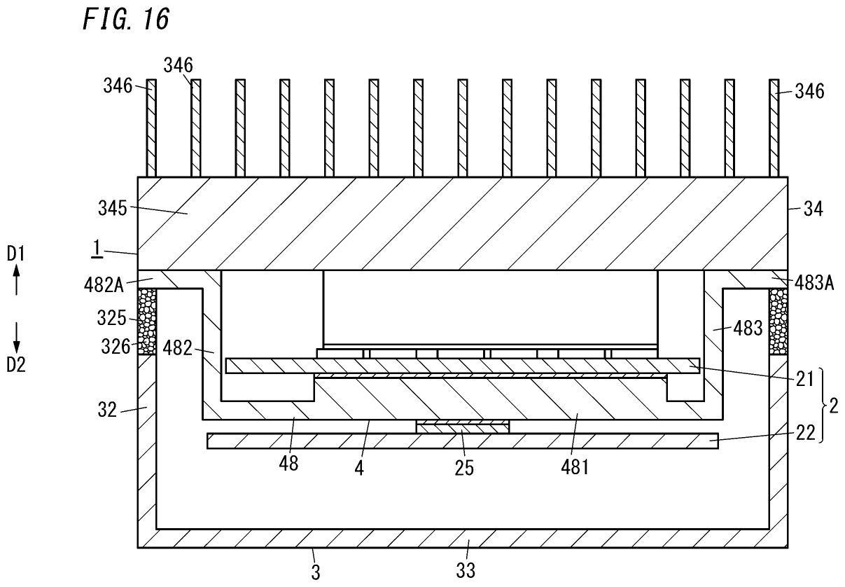

FIG. 16 is a sectional view of a circuit device 1 included in an electromechanical unit 9 according to a seventh variation. The fundamental configuration of the electromechanical unit 9 according to the seventh variation is the same as that of the fifth variation. Note that any constituent element of the seventh variation to be described below, having the same configuration as a counterpart of the fifth variation, will be designated by the same reference numeral as that counterpart's, and a detailed description thereof will be omitted as appropriate herein.

In the circuit device 1 according to the seventh variation, the peripheral wall portion 32 thereof does not include any solid structure 327 adjacent to a porous structure 326. That is to say, in the seventh variation, the porous structure 326 forming part of the peripheral wall portion 32 is formed from the inner end through the outer end of the peripheral wall portion 32.

The peripheral wall portion 32 according to the seventh variation may also be manufactured by forming only a part of the peripheral wall portion 32 as the porous structure 326 when a peripheral wall portion 32 of aluminum is formed by using a 3D printer, for example.

### (8) Eighth Variation

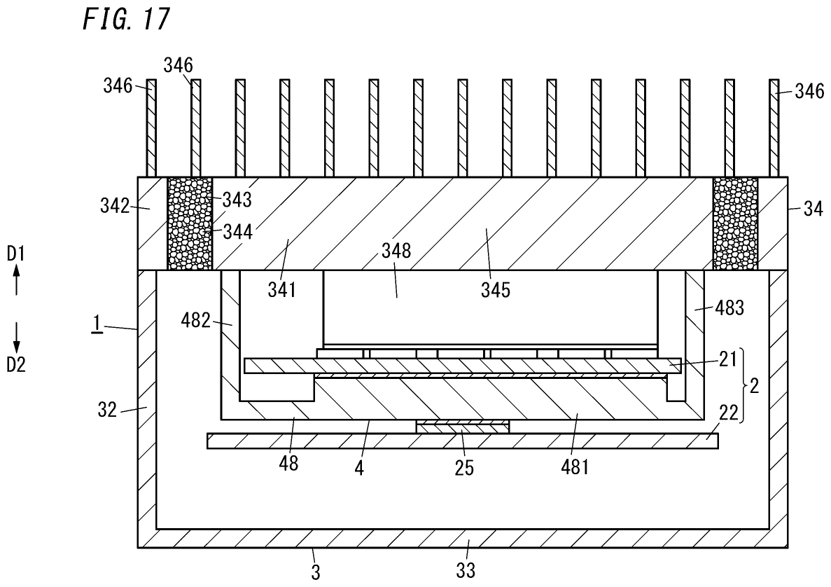

FIG. 17 is a sectional view of a circuit device 1 included in an electromechanical unit 9 according to an eighth variation. The fundamental configuration of the electromechanical unit 9 according to the eighth variation is the same as that of the first variation. Note that any constituent element of the eighth variation to be described below, having the same configuration as a counterpart of the first variation, will be designated by the same reference numeral as that counterpart's, and a detailed description thereof will be omitted as appropriate herein.

A heat sink 34 included in the circuit device 1 according to the eighth variation includes a first heat-dissipating portion 341, a second heat-dissipating portion 342, and a thermal insulator 343.

In the heat sink 34, the first heat-dissipating portion 341 is a portion to which the heat transfer member 4 is connected both mechanically and thermally. The first portion 481 and second portion 482 of the heat transfer member 4 are mechanically and thermally connected to the first heat-dissipating portion 341. The first heat-dissipating portion 341 is formed as one part of the lid portion 345. The connection portion 348 of the heat sink 34 protrudes from the first heat-dissipating portion 341 in the second direction D2.

In the heat sink 34, the second heat-dissipating portion 342 is a portion to which the peripheral wall portion 32 is connected both mechanically and thermally. The second heat-dissipating portion 342 is formed as another part of the lid portion 345. The second heat-dissipating portion 342 is located to surround the first heat-dissipating portion 341 along the entire circumference. The second heat-dissipating portion 342 is formed as an outer peripheral edge portion of the lid portion 345.

In the heat sink 34, the thermal insulator 343 is a portion provided between the first heat-dissipating portion 341 and the second heat-dissipating portion 342. The thermal insulator 343 is a portion having a lower thermal conductivity than the first heat-dissipating portion 341 and the second heat-dissipating portion 342. It is preferable that the thermal insulator 343 have the shape of a ring connected along the entire circumference of the lid portion 345. Alternatively, the thermal insulator 343 may also have the shape of an imperfect ring disconnected at least at one point along the entire circumference of the lid portion 345.

The thermal insulator 343 is a porous portion 344 having a large number of pores. The heat sink 34 according to the eighth variation may be manufactured by forming only a part of the lid portion 345 as the porous portion 344 when a lid portion 345 of aluminum is formed by using a 3D printer, for example.

The electromechanical unit 9 according to the eighth variation which includes the thermal insulator 343 described above allows for reducing the transfer of the heat generated in the motor device 8 to the first heat-dissipating portion 341 of the heat sink 34 through the peripheral wall portion 32 of the circuit device 1. This allows for reducing the transfer of the heat generated in the motor device 8 to the circuit board 2 through the heat sink 34.

Note that the embodiment and its variations described above with reference to the accompanying drawings are only an exemplary one of various embodiments of the present disclosure and its variations, and should not be construed as limiting. Rather, the exemplary embodiment and its variations may be readily modified in various manners depending on a design choice or any other factor without departing from a true spirit and scope of the present disclosure. It should also be noted that the variations to be described below may be adopted in combination as appropriate.

### 3. Recapitulation

As can be seen from the foregoing description of the exemplary embodiment and its variations, a circuit device (1) according to a first aspect includes: a circuit board (2) including a circuit component (25) to drive a motor; a case (3) that houses the circuit board (2); and a heat transfer member (4) housed in the case (3) and thermally connected to the circuit board (2). The case (3) includes a peripheral wall portion (32) and a heat sink (34) joined to the peripheral wall portion (32). At least part of the circuit board (2) is located between the heat sink (34) and the heat transfer member (4). The heat transfer member (4) is thermally connected to the heat sink (34) and the at least part of the circuit board (2).

According to this aspect, heat is transferred from the circuit board (2) to the heat sink (34) via the heat transfer member (4) located opposite from the heat sink (34) with respect to the circuit board (2). Therefore, this aspect allows for transferring heat from the circuit board (2) to the heat sink (34) through a plurality of paths and effectively dissipating heat from the circuit board (2) to an external environment via the heat sink (34).

In a circuit device (1) according to a second aspect, which may be implemented in conjunction with the first aspect, the peripheral wall portion (32) has an opening (320). The heat sink (34) is joined to the peripheral wall portion (32) to close the opening (320).

According to this aspect, combining the peripheral wall portion (32) and the heat sink (34) allows for downsizing the case (3) for use to house the circuit board (2).

In a circuit device (1) according to a third aspect, which may be implemented in conjunction with the first or second aspect, the circuit board (2) includes a first circuit board (21) and a second circuit board (22). The first circuit board (21) is located between the heat sink (34) and the heat transfer member (4). The heat transfer member (4) is located between the first circuit board (21) and the second circuit board (22). The heat transfer member (4) is thermally connected to both the heat sink (34) and the first circuit board (21).

According to this aspect, heat is transferred from the first circuit board (21) to the heat sink (34) via the heat transfer member (4) located opposite from the heat sink (34) with respect to the first circuit board (21). Therefore, this aspect allows for transferring heat from the first circuit board (21) to the heat sink (34) through a plurality of paths and effectively dissipating heat from the first circuit board (21) to the external environment via the heat sink (34).

In a circuit device (1) according to a fourth aspect, which may be implemented in conjunction with the third aspect, the first circuit board (21) is a circuit board serving as a power circuit for supplying electric power to drive a motor. The second circuit board (22) is a circuit board serving as a control circuit to activate the power circuit.

This aspect allows for effectively dissipating heat from the power circuit board to the external environment via the heat transfer member (4) and the heat sink (34).

In a circuit device (1) according to a fifth aspect, which may be implemented in conjunction with the third or fourth aspect, the heat transfer member (4) is thermally connected to the heat sink (34), the first circuit board (21), and the second circuit board (22).

This aspect allows for effectively dissipating heat from both the first circuit board (21) and the second circuit board (22) to the external environment via the heat transfer member (4) and the heat sink (34).

In a circuit device (1) according to a sixth aspect, which may be implemented in conjunction with any one of the third to fifth aspects, the heat transfer member (4) includes a first connection portion (41) thermally connected to the first circuit board (21), a second connection portion (42) thermally connected to the second circuit board (22), and a thermal insulator (43) provided between the first connection portion (41) and the second connection portion (42).

This aspect allows for effectively dissipating heat from both the first circuit board (21) and the second circuit board (22) to the external environment via the heat transfer member (4) and the heat sink (34). In addition, this aspect may also reduce the chances of the heat generated on the first circuit board (21) affecting the second circuit board (22) and may also reduce the chances of the heat generated on the second circuit board (22) affecting the first circuit board (21).

In a circuit device (1) according to a seventh aspect, which may be implemented in conjunction with the sixth aspect, the thermal insulator (43) is an air gap (430) provided for the heat transfer member (4).

According to this aspect, a simple structure in which the air gap (430) is provided for the heat transfer member (4) allows for effectively reducing the chances of the heat generated on the first circuit board (21) affecting the second circuit board (22) and reducing the chances of the heat generated on the second circuit board (22) affecting the first circuit board (21).

A circuit device (1) according to an eighth aspect, which may be implemented in conjunction with any one of the first to seventh aspects further includes a thermal insulator member (62) interposed between the peripheral wall portion (32) and the heat sink (34).

This aspect allows for reducing the transfer of the heat generated in the motor device (8) to the circuit board (2) through the peripheral wall portion (32) and heat sink (34) of the circuit device (1).

In a circuit device (1) according to a ninth aspect, which may be implemented in conjunction with any one of the first to eighth aspects, part of the peripheral wall portion (32) is configured as a thermal insulation structure (325) having a lower thermal conductivity than a remaining part of the peripheral wall portion (32).

This aspect allows for reducing the transfer of the heat generated in the motor device (8) to the circuit board (2) through the peripheral wall portion (32) and heat sink (34) of the circuit device (1).

In a circuit device (1) according to a tenth aspect, which may be implemented in conjunction with the ninth aspect, the thermal insulation structure (325) is a porous structure (326).

According to this aspect, the simple structure in which part of the peripheral wall portion (32) has the porous structure (326) allows for reducing the transfer of the heat generated in the motor device (8) to the circuit board (2) through the peripheral wall portion (32) and heat sink (34) of the circuit device (1).

In a circuit device (1) according to an eleventh aspect, which may be implemented in conjunction with any one of the first to tenth aspects, the heat sink (34) includes: a first heat-dissipating portion (341) thermally connected to the heat transfer member (4); a second heat-dissipating portion (342) thermally connected to the peripheral wall portion (32); and the thermal insulator (343) provided between the first heat-dissipating portion (341) and the second heat-dissipating portion (342).

This aspect allows for reducing the transfer of the heat generated in the motor device (8) to the circuit board (2) through the heat sink (34).

In a circuit device (1) according to a twelfth aspect, which may be implemented in conjunction with the eleventh aspect, the thermal insulator (343) is a porous portion (344).

According to this aspect, the simple structure in which part of the heat sink (34) is the porous portion (344) allows for reducing the transfer of the heat generated in the motor device (8) to the circuit board (2) through the heat sink (34).

An electromechanical unit (9) according to a thirteenth aspect includes the circuit device (1) according to any one of the first to twelfth aspects and a motor device (8) coupled to the case (3) of the circuit device (1).

According to this aspect, heat is transferred from the circuit board (2) to the heat sink (34) via the heat transfer member (4) located opposite from the heat sink (34) with respect to the circuit board (2). Therefore, this aspect allows for transferring heat from the circuit board (2) to the heat sink (34) through a plurality of paths and effectively dissipating heat from the circuit device (1) to the external environment via the heat sink (34).

An electromechanical unit (9) according to a fourteenth aspect, which may be implemented in conjunction with the thirteenth aspect, further includes a thermal insulator member (61) interposed between the motor device (8) and the circuit device (1).

According to this aspect, the simple structure in which the thermal insulator member (61) is interposed between the motor device (8) and the circuit device (1) allows for reducing the transfer of the heat generated in the motor device (8) to the circuit board (2) through the heat sink (34).

### REFERENCE SIGNS LIST

1 Circuit Device
2 Circuit Board
21 First Circuit Board
22 Second Circuit Board
25 Circuit Component
3 Case
32 Peripheral Wall Portion
325 Thermal Insulation Structure
326 Porous Structure
34 Heat Sink
341 First Heat-Dissipating Portion
342 Second Heat-Dissipating Portion
343 Thermal Insulator
344 Porous Portion
4 Heat Transfer Member
41 First Connection Portion
42 Second Connection Portion
43 Thermal Insulator
430 Air Gap
61 Thermal Insulator Member
62 Thermal Insulator Member
8 Motor Device
9 Electromechanical Unit

1. A circuit device comprising:
a circuit board including a circuit component configured to drive a motor;
a case that houses the circuit board; and
a heat transfer member housed in the case and thermally connected to the circuit board,
the case including a peripheral wall portion and a heat sink joined to the peripheral wall portion,
at least part of the circuit board being located between the heat sink and the heat transfer member, and
the heat transfer member being thermally connected to the heat sink and the at least part of the circuit board.

2. The circuit device of claim 1, wherein
the peripheral wall portion has an opening and the heat sink is joined to the peripheral wall portion to close the opening.

3. The circuit device of claim 1, wherein
the circuit board includes a first circuit board and a second circuit board,
the first circuit board is located between the heat sink and the heat transfer member,
the heat transfer member is located between the first circuit board and the second circuit board, and
the heat transfer member is thermally connected to both the heat sink and the first circuit board.

4. The circuit device of claim 3, wherein
the first circuit board is a circuit board serving as a power circuit configured to supply electric power to drive a motor, and
the second circuit board is a circuit board serving as a control circuit configured to activate the power circuit.

5. The circuit device of claim 3, wherein
the heat transfer member is thermally connected to the heat sink, the first circuit board, and the second circuit board.

6. The circuit device of claim 3, wherein
the heat transfer member includes: a first connection portion thermally connected to the first circuit board; a second connection portion thermally connected to the second circuit board; and a thermal insulator provided between the first connection portion and the second connection portion.

7. The circuit device of claim 6, wherein
the thermal insulator is an air gap provided for the heat transfer member.

8. The circuit device of claim 1, further comprising a thermal insulator member interposed between the peripheral wall portion and the heat sink.

9. The circuit device of claim 1, wherein
part of the peripheral wall portion is configured as a thermal insulation structure having a lower thermal conductivity than a remaining part of the peripheral wall portion.

10. The circuit device of claim 9, wherein the thermal insulation structure is a porous structure.

11. The circuit device of claim 1, wherein
the heat sink includes: a first heat-dissipating portion thermally connected to the heat transfer member; a second heat-dissipating portion thermally connected to the peripheral wall portion; and the thermal insulator provided between the first heat-dissipating portion and the second heat-dissipating portion.

12. The circuit device of claim 11, wherein the thermal insulator is a porous portion.

13. An electromechanical unit comprising;
the circuit device of claim 1; and
a motor device coupled to the case of the circuit device.

14. The electromechanical unit of claim 13, further comprising a thermal insulator member interposed between the motor device and the circuit device.
